(19) United States
(12) Patent Application Publication
(10) Pub. No.: US 2014/0048842 A1
(43) Pub. Date: Feb. 20, 2014

(54) LED LAMP AND MANUFACTURE METHOD THEREOF

(71) Applicants: Zhaopeng Yu, Shanghai (CN); Fangyi Xiao, Shanghai (CN)

(72) Inventors: Zhaopeng Yu, Shanghai (CN); Fangyi Xiao, Shanghai (CN)

(21) Appl. No.: 14/114,149

(22) PCT Filed: May 11, 2012
(86) PCT No.: PCT/CN2012/075322

§ 371 Date: Oct. 25, 2013

(30) Foreign Application Priority Data
May 13, 2011 (CN) 201110123030.8

(51) Int. Cl. H01L 33/64

(52) U.S. Cl. CPC H01L 33/642
USPC 257/99; 438/26

(57) ABSTRACT

An LED lamp comprises an LED light source (1), a cup-shaped radiator (2) and a power supply (3), electrodes (1a) and a heat sink (1b) are provided at the back side of the LED light source (1). The LED light source (1) is provided at the inner side of the bottom of the cup-shaped radiator (2), electrodes (7) are provided at the bottom of the cup-shaped radiator (2). The power supply (3) is provided at the outer side of the bottom of the cup-shaped radiator (2). The electrodes (1a) of the LED light source (1) and the power supply (3) are directly connected with two ends of the electrodes (7) of the cup-shaped radiator (2) respectively. A manufacture method of the LED lamp is also provided. The heat-conduction efficiency of the LED lamp is high, and the heat-dissipation structure of the whole lamp is effectively improved. And heat is dissipated by radiating, and therefore the stability in the indoor illumination environment is high. The manufacture process has high automation degree.

### FIELD OF THE INVENTION

This invention is related to the design of entire set of one LED structure, heat sink/heat conduction and its manufacture method, especially is related to a kind of LED lamp and its manufacture method used in the MR16 LED lamp.

### DESCRIPTION OF RELATED ART

Halogen reflector lamp (MR16 LED) is a kind of small size spot light mainly used for indoor lighting. The current MR16 LED lamp is featured with low watts and low heat value, therefore, heat sink problem is usually not considered. While with increasing of watts of the MR16 LED spot light, its heat value increased accordingly, therefore, the temperature of LED spot light increased when light size not changed. When the temperature is higher than its working temperature, its work stability and usage period will be seriously impacted. Under this circumstance, solving the problem for LED spot light heat sink becomes very important.

At present, the bottom of MR16 LED light source is generally the PCB base or the Aluminum base 13, As shown in FIG. 1, the bottom is connected with spotlight 14 via screw 12 or the adhesive colloid, LED electrodes is welded with PCB or Luminal base 13 via tin solder and connect with the bottom power supply via electrical wire. The thermal conductivity of the PCB base or the Luminal base inside the LED light source structure is poor which is generally act in 0.5-1.5 W/m·k, the performance seriously affected the export of heating inside LED light source. Meanwhile, the high temperature of 180□ is needed when LED electrodes welded with PCB or Luminal base 13 via tin solder which affect the LED chip and decrease its service life and increase the defect rate of finish goods. While the lead inside of the tin solder is toxic substances which hazardous to human health and causes environmental pollution.

While the manufacture of LED lamp products are manual operation, the defective rate of components assemble is very high.

### SUMMARY OF THE INVENTION

This invention is aimed to provide a new design concept for LED lamp, which is especially applied to the MR16 and other indoor lightings. The invention is mainly used to solve the problems and disadvantages of the current LED lamps such as bad Thermal conductive adhesive structure, poor cooling performance and safety, Solder paste welding and manual operation. LED lamp in this invention holds advantages of good cooling performance, making high efficient LED lamp under the same specifications which greatly improved the automatical manufacture level.

In order to solve the technical problems listed above and optimizing the manufacture process and enhance the performance of LED lamp, the invention implement via the following method and technology.

This invention provides a LED lamp, which comprises: a LED light source, electrodes and a heat sink are provide on the back of the LED light source; a cup-shaped radiator, the LED light source is provided inner side of the cup-shaped radiator, electrodes are provided at the bottom of the cup-shaped radiator; a power supply is provided outer side of the bottom of the cup-shaped radiator; the electrodes of the LED light source and the power supply directly connected with two ends of the electrodes of the cup-shaped radiator respectively.

This invention provides a LED lamp, which the cup edge of the cup-shaped radiator is wave shaped.

This invention provides a LED lamp, which the cup edge of the cup-shaped radiator further includes: an innermost reflective layer, an outmost thermal plastic layer and a metal insert set between the reflective layer and the thermal plastic layer.

This invention provides a LED lamp, which the metal insert has a flat bottom with through hole on the flat bottom, insulating material is embedded in the through hole and the electrodes of the cup-shaped radiator are embedded into the insulating materials; the insulating material includes Rubber, plastic, or plastic insulation.

This invention provides a LED lamp, which the top of its power supply is acicular or columnar structure.

This invention provides a LED lamp, which the material of reflective layer for the invention LED lamp are reflective film, reflective coatings, or reflective ink.

This invention provides a manufacture method for the invention LED lamp that include the following steps: Step 1: dispensing one end of electrodes of cup-shaped radiator and the heat sink on the outer side of bottom of cup-shaped radiator by the dispenser. Step 2: Install the power supply to the outside of bottom of the cup-shaped radiator via surface mounting technology. Step 3: fix the installed cup-shaped radiator and the power supply. Step 4: dispensing the other end of the electrodes of the cup-shaped radiator and the heat sink on the inner side of bottom of cup-shaped radiator by the dispenser. Step 5: install LED light source in the inner bottom of cup-shaped radiator via surface mounting technology. Step 6: burn-in the installed LED lamp.

This invention provides A manufacture method for the LED lamp, which is dispensing the electrodes with conductive adhesive while the heat sink with thermally conductive adhesive during the above step 1 to step 4.

This invention provides A manufacture method for the LED lamp, which the thermally conductive adhesive includes Epoxy thermal adhesive, thermal grease, thermal silicone, thermal pads, or phase change materials.

According to the above technical solution, the technical effect of this invention are:

1. Compared with the current LED technology, the out layer of the cup-shaped radiator edge is covered by radiation cooling plastic which can enhance stability of cooling for lighting under indoor circumstance, wave shaped cup edge structure enlarge the cooling area, meanwhile, the middle metal insert could help improve the diffusivity of heat and make heat rapidly be conducted to cooling plastic. While the inner reflective layer in cup could improve the luminous efficiency. All the cup is constructed by cooling plastic and metal insert which make the entire lighting lightweight and higher security.

2. The bottom of the LED light source in this invention is not PCB, the electrodes of LED light source and the top of power supply is connected with conductive electrodes by conductive adhesive such as silver adhesive rather than by using the solder paste which is used in current process. Moreover, LED light source is not fixed by screw which simplify the product structure and reduce multi-layer medium, this method not only help heat conduction but also reduce the producing cost.

3. This invention simplified the product structure. The conductive adhesive and thermal conductive adhesive could be used via dispenser. LED light source could be automatically mounted via SMT surface mounting technology which realized the automatically assembling of LED products and greatly improved the LED producing efficiency and reduced the product defect rate. The current manual assembling method is low efficient and high defect rat.

In order to specified the specification items, the further instruction for this invention are combined with specified practice cases below:

### DESCRIPTION OF DRAWINGS

FIG. 1 shows the current LED lamp structure.

FIG. 2 shows the structure explosive view of the LED lamp of this invention.

FIG. 3 shows the structure of invention LED light source in LED lamp of this invention.

FIG. 4 shows the graphic model for cup-shaped radiator in the LED lamp of this invention, FIG. 4(a) shows the overall drawing of cup-shaped radiator; and FIG. 4(b) shows explosive view for the three layer of the cup-shaped radiator.

FIG. 5 shows the vertical view of cup-shaped radiator bottom in the LED lamp of this invention.

FIG. 6 is the cutaway view for A-A line in FIG. 5.

FIG. 7 shows the installation structure of the LED light source, cooling insulation body and power supply in the LED lamp of this invention, FIG. 7(a) shows the installing power supply to outside of cup-shaped radiator, FIG. 7(b) shows the installing LED light source onto the inner side of cup-shaped radiator.

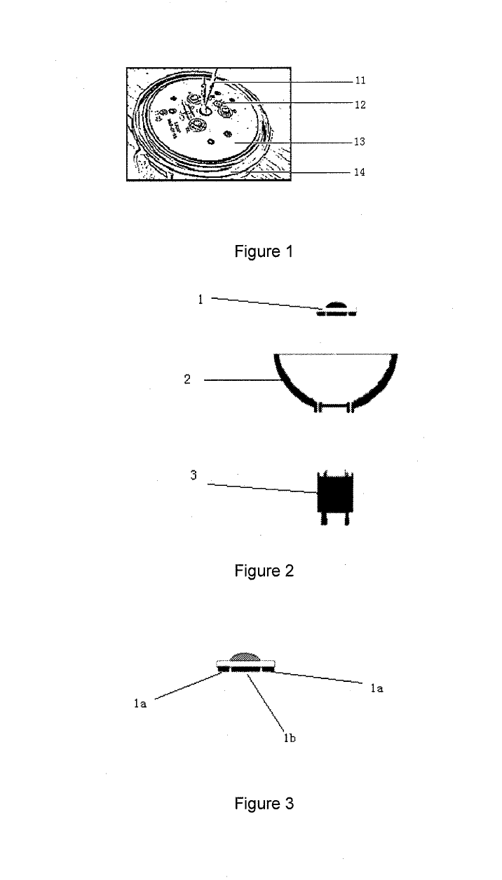

### DETAILED DESCRIPTION OF THE PREFERRED EMBODIMENTS

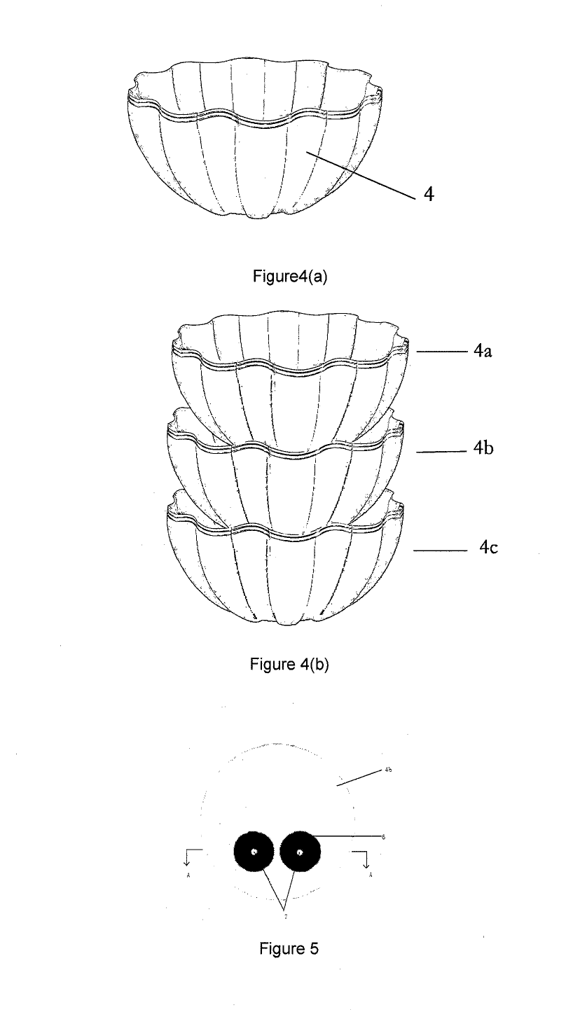

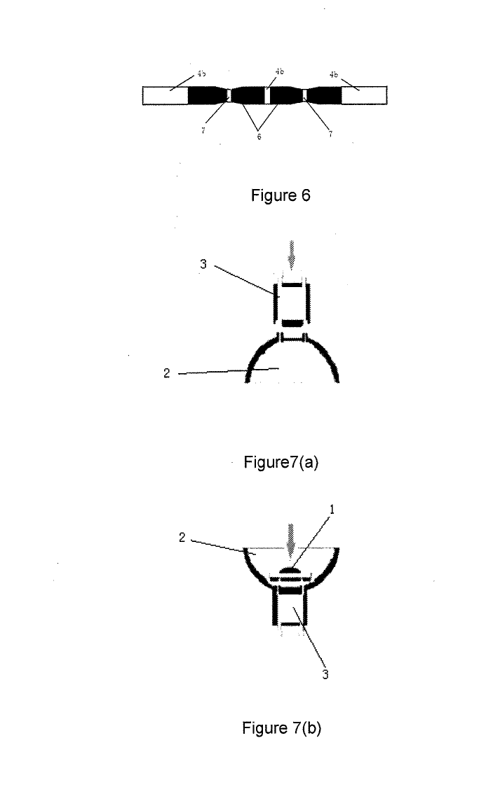

FIG. 2 is the structure drawing for the LED lamp of this invention. FIG. 3 is the structure drawing for LED light source in the LED lamp of this invention. FIG. 4 is the graphic model of cup-shaped radiator in the LED lamp of this invention. FIG. 4(a) is the entire drawing of the cup-shaped radiator; FIG. (4b) is the explosive view of three layer structure of the cup-shaped radiator.

The LED lamp include: LED light source 1, cup-shaped radiator 2, power supply 3. The LED light source 1 is set on inner side of edge of cup-shaped radiator 2 while the power supply 3 is set in outer side edge.

The electrodes 1a and heat sink 1b are set on back of LED light source 1 which are shown in FIG. 3. As shown in FIG. 4(a), the cup edge 4 of cup-shaped radiator 2 is wave shaped. As shown in FIG. 4(b), the cup edge 4 include the innermost reflective layer 4a, the outmost cooling plastic layer and the metal insert 4b set on a flat bottom which set between the two layers. The material of reflective layer 4a are reflective film, reflective coatings, or reflective ink. As shown in FIG. 2, the top of power supply 3 is acicular or columnar structure.

FIG. 5 shows the vertical view of cup-shaped radiator bottom in the LED lamp of this invention; the FIG. 6 shows the cutaway view of A-A line in the FIG. 5.

In FIG. 5, the through hole is set on the bottom of the mental insert 4b. The insulating material 6 is embedded in the through hole. The electrodes 7 of cup-shaped radiator 2 are embedded into the insulating material 6. The insulating material 6 could be rubber, plastic, plastic insulation, or the other material.

The cup-shaped radiator 2 is mainly cooled via radiation cooling way which changed the cooling method for current products. The radiation cooling way can enhance stability of cooling for lighting under indoor circumstance. The insulation cool body 2 is combined by three insulation layers, the outmost layer of edge 4 of cup-shaped radiator is radiation wave cooling plastic layer 4c which enhance stability of lighting cooling under indoor circumstance. The metal insert 4b in middle could improve the diffusivity of heat and make heat rapidly be conducted to cooling plastic which enhance the heat conductivity of entire lighting. Meanwhile the reflective layer in cup could improve the luminous efficiency. All the cup is constructed by cooling plastic and metal insert which make the entire lighting lightweight and higher security.

Meanwhile, the edge 4 of insulation cooling body 2 is wave shaped structure which enlarge the radiation cooling area and stay the same thickness as current one and do neither influence the Transverse thermal conduct efficiency of the metal insert 4b nor its conduct distance. The invention make the most of each materials advantages.

The bottom of LED light source 1 do not use the substrates such as glass fiber, aluminum nor ceramic plates in the invention LED lamp. The heat conductivity is very low for those bottom substrates which seriously affect the LED chips heat conduction. The invention remove the medium substrates which reduce the heat resistance, producing processes and the producing cost.

The bottom of cup-shaped radiator 2 is holed which is embedded with accordingly electrodes 7 on the position of LED light source 1 which make the electrodes 1a of LED light source 1 connect with power supply 3 through the electrodes 7 of cup-shaped radiator. The LED light source 1 connect with heat sink 1b with insulation heat conductive materials. The electrodes 1a of LED light source 1 connect with electrodes 7 through the conductive adhesive.

The top of power supply 3 is acicular structure. The heat sink on the top of the power supply connect with the bottom of cup-shaped radiator 2 via conductive adhesive and connect with one end of electrodes 7 of cup-shaped radiator 2 via sliver adhesive which becomes electrocircuit for LED light source.

Below is the specification instruction for this invention LED lamp manufacture method:

The method for manufacturing of the LED lamp of this invention is below:

Using the current injection molding technology to merge the reflective layer 4a, the metal insert 4b, thermal plastic layer 4c and electrodes 7 into the form of the same thickness integrated cup-shaped radiator 2. This structure integrated optical systems, electronic systems and thermal systems of the lamp. The process is very easy for the manufacturer which is not instructed here.

Step 1: dispensing the electric conductive adhesive on one end of electrodes 7 of the cup-shaped radiator 2 and dispensing the thermally conductive adhesive on the heat sink outer side of the cup-shaped radiator 2 by the dispenser.

Step 2: install the power supply 3 on the accordingly spot of outside of bottom of the cup-shaped radiator 2 via surface mounting technology.

Step 3: fix the installed cup-shaped radiator 2 and the power supply 3 after 30 minutes cooling.

Step 4: dispensing the electric conductive adhesive on the other end of electrodes (7) of the cup-shaped radiator 2 and the thermally conductive adhesive on the heat sink inner side of the cup-shaped radiator 2 by the dispenser.

Step 5: install LED light source 1 in the inner bottom of cup-shaped radiator 2 via surface mounting technology.

Step 6: burn-in the installed LED lamp under 100 degree of high temperature.

Compared the manual products and its producing process, the LED lamp made out of the above processes and method could improve heat conductivity of the entire lighting, the general heat conductivity ≧20 w/m·k, moreover, the invention greatly improve the anti-electronic leakage level which make the lighting successfully pass the 4000V high pressure testing which ensure the security of LED lamp. Because all the producing and assembling process are throughout automation in the invention method which enhance the product quality, producing efficiency and greatly decrease the manufacturing cost.

All introduced above is description of exemplary embodiments which are given for illustration of said invention and are not intended to be limited thereof. All changes and decoration based on this invention content are within this invention's technical area.

1. A LED lamp, wherein comprises:
a LED light source (1), electrodes (1a) and a heat sink (1b) are provided on the back of the LED light source (1);
a cup-shaped radiator (2), The LED light source (1) is provided inner side of the bottom of the cup-shaped radiator (2), an electrodes (7) is provided at the bottom of the cup-shaped radiator (2);
a power supply (3) is provided outer side of the bottom of the cup-shaped radiator (2);
the electrodes (1a) of the LED light source (1) and the power supply (3) directly connected with two ends of the electrodes (7) of the cup-shaped radiator (2) respectively.

2. The LED lamp of claim 1, wherein cup edge (4) of the cup-shaped radiator (2) is wave shaped.

3. The LED lamp of claim 2, wherein the cup edge (4) of the cup-shaped radiator (2) further includes: an innermost reflective layer (4a), an outmost thermal plastic layer (4c) and a metal insert (4b) which is set between the reflective layer (4a) and the thermal plastic layer (4c).

4. The LED lamp of claim 3, wherein the metal insert (4b) has a flat bottom with through hole on the flat bottom, insulating material (6) is embedded in the through hole and the electrodes (7) of the cup-shaped radiator (2) are embedded into the insulating materials (6); the insulating material (6) includes Rubber, plastic, or plastic insulation.

5. The LED lamp of claim 1, wherein the top of the power supply (3) is acicular or columnar structure.

6. The LED lamp of claim 3, wherein the material of the reflective layer (4a) are reflective film, reflective coatings, or reflective ink.

7. A manufacture method for the LED lamp of claim 1, wherein comprises the following steps:
Step 1: dispensing one end of electrodes (7) of the cup-shaped radiator (2) and the heat sink on the outer side of bottom of cup-shaped radiator (2) by the dispenser;
Step 2: install the power supply (3) to the outside of bottom of the cup-shaped radiator (2) via surface mounting technology;
Step 3: fix the installed cup-shaped radiator (2) and the power supply (3);
Step 4: dispensing the other end of the electrodes (7) of the cup-shaped radiator (2) and the heat sink on the inner side of bottom of cup-shaped radiator (2) by the dispenser;
Step 5: install LED light source (1) in the inner bottom of cup-shaped radiator (2) via surface mounting technology;
Step 6: burn-in the installed LED lamp.

8. A manufacture method for the LED lamp of claim 7, wherein dispensing the electrodes with conductive adhesive while the heat sink with thermally conductive adhesive during the step 1 to step 4.

9. A manufacture method for the LED lamp of claim 7, wherein the thermally conductive adhesive includes Epoxy thermal adhesive, thermal grease, thermal silicone, thermal pads, or phase change materials.
